(19) United States
(12) Patent Application Publication
(10) Pub. No.: US 2012/0021542 A1
(43) Pub. Date: Jan. 26, 2012

(54) METHOD OF PACKAGING LIGHT EMITTING DEVICE

(75) Inventor: SHEN-BO LIN, Hukou (TW)

(73) Assignee: ADVANCED OPTOELECTRONIC TECHNOLOGY, INC., Hsinchu Hsien (TW)

(21) Appl. No.: 13/015,593

(22) Filed: Jan. 28, 2011

(30) Foreign Application Priority Data
Jul. 22, 2010 (CN) 201010230810.8

(51) Int. Cl. H01L 33/50

(52) U.S. Cl. 438/27; 257/E33.059

(57) ABSTRACT

A method of packaging a light emitting device includes the following steps: providing a base; forming a mask on the base, the mask defining a plurality of holes therein; positioning a certain amount of glue in each of the holes; securing a film on the mask, a plurality of light emitting elements being positioned on the film, and each of the light emitting elements being positioned in a corresponding hole and adhered by the glue in the corresponding hole; separating the light emitting elements from the film and removing the film from the mask; and removing the mask from the base.

### BACKGROUND

1. Technical Field

The present disclosure relates generally to light emitting devices, and more particularly to a method of packaging a light emitting diode (LED).

2. Description of Related Art

LEDs are solid state light emitting devices formed of semiconductors, which are more stable and reliable than other conventional light sources such as incandescent bulbs. Thus, LEDs are being widely used in various fields such as numeral/character displaying elements, signal lights, light sources for lighting and display devices. When in use, providing LEDs in packages can provide protection, color selection, focusing and the like for light emitted by the LEDs. Generally, a process of packaging an LED chip includes bonding, encapsulating, baking, cutting etc.

In a typical bonding process, the LED chip is secured on a base via glue. If LED packages are manufactured in batch, a plurality of LED chips should be secured on the base one by one. Such a method fails to satisfy the demand of manufacture in batch due to the shortcomings thereof. First, the LED chips are prone to disengage from the base for imprecisely positioning of the LED chips and glue, and uneven distribution of the glue. In addition, the bonding of the LED chip should be repeated time and time again, resulting in a low efficiency of the packaging.

What is needed therefore is a method of packaging a light emitting device which can overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a flow chart of a method of packaging a light emitting device in accordance with an embodiment of the present disclosure.

FIGS. 2-7 are cross sectional views of a package of a light emitting device obtained by different steps of the method shown in FIG. 1.

### DETAILED DESCRIPTION

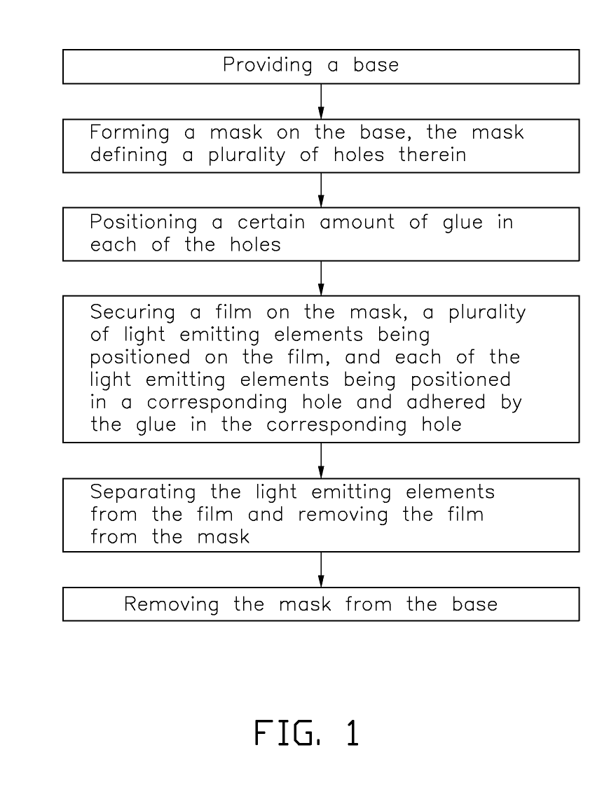

FIG. 1 illustrates a flow chart of a method of packaging a light emitting device. The method includes the following steps:

Step A, providing a base 10;

Step B, forming a mask 20 on the base 10, the mask 20 defining a plurality of holes 22 therein;

Step C, placing a certain amount of glue 30 in each of the holes 22;

Step D, providing a film 40 with a plurality of light emitting elements 42 positioned thereon, and securing the film 40 on the mask 20, during which, each of the light emitting elements 42 is positioned in one of the holes 22 and secured by the glue 30;

Step E, separating the light emitting elements 42 from the film 40, and removing the film 40 from the mask 20; and

Step F, removing the mask 20 from the base 10.

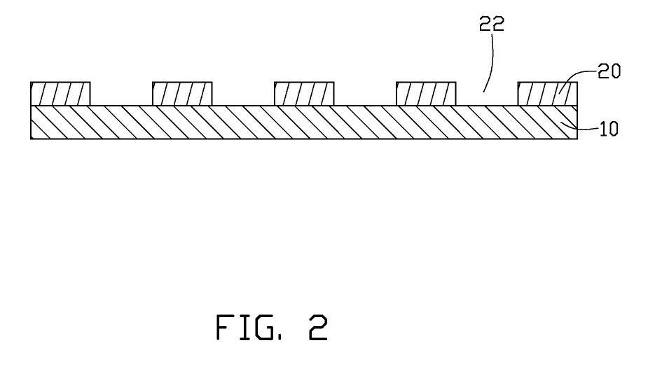

The present disclosure now will be described in detail hereinafter with reference to FIGS. 2-7. Referring to FIG. 2, the base 10 is provided, and the mask 20 with patterned holes 22 defined therein is formed on the base 10. In some embodiments, the base 10 can have electrical structures (not shown) formed thereon for electrically connecting with the light emitting elements 42.

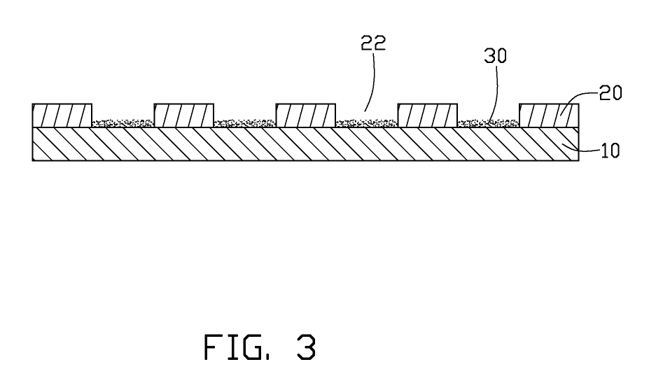

Referring to FIG. 3, the glue 30 is positioned in the holes 22 by a technology of printing, such as screen printing. Specifically, the glue 30 can be positioned in the holes 22 in one time, whereby the efficiency of bonding the light emitting elements 42 can be improved.

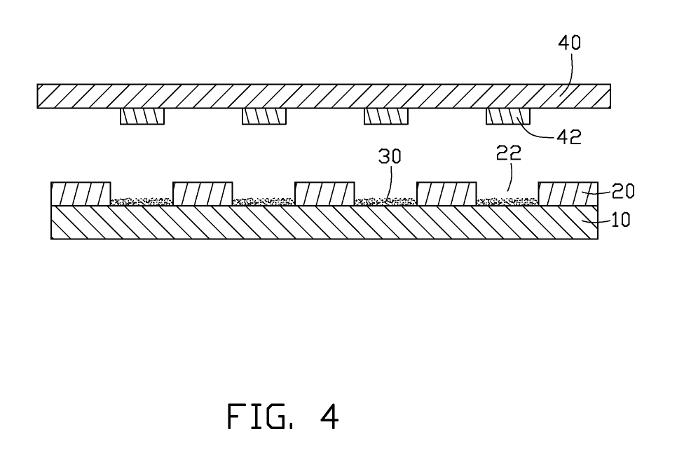

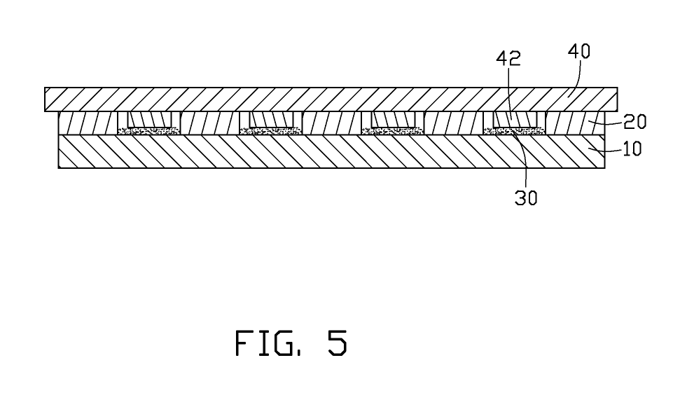

Referring to FIGS. 4-5, the light emitting elements 42 are adhered on the film 40. The light emitting elements 42 can be light emitting diodes (LEDs), laser diodes and/or other semiconductor devices which include one or more semiconductor layers, which may include silicon, silicon carbide, gallium nitride and/or other semiconductor materials. In the present embodiment, the light emitting elements 42 are LEDs. It is understood that, ultraviolet, blue and/or green LEDs may be provided. The film 40 is an adhesive thin film. The film 40 is brought to be attached on the mask 20, and the light emitting elements 42 each are positioned in a corresponding hole 22. The light emitting elements 42 are secured on the base 10 via the adherence of the glue 30 by pressing the film 40 onto the mask 20.

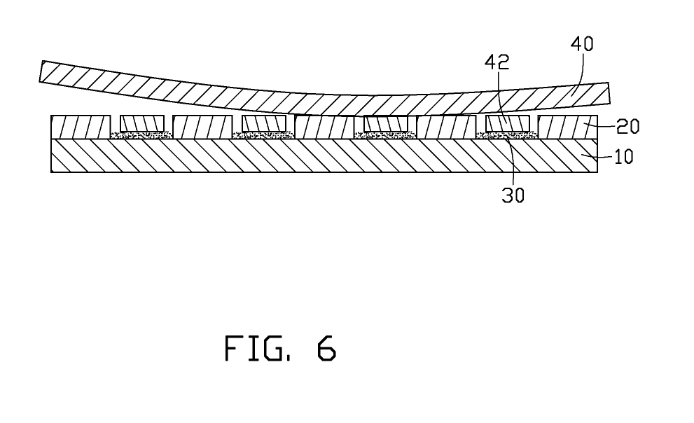

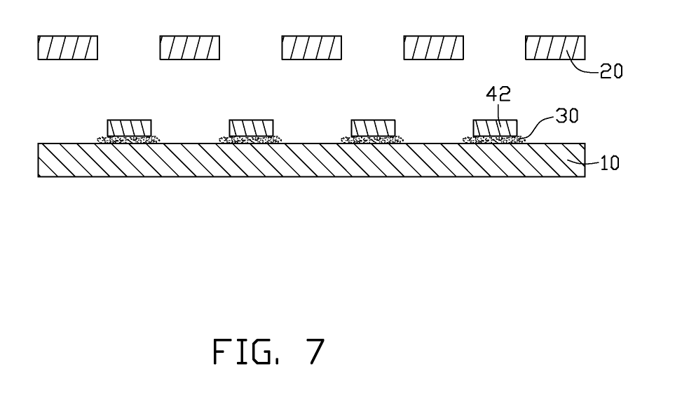

After that, the stickiness of the film 40 to the light emitting elements 42 is eliminated by a process of subjecting the film 40 to ultraviolent (UV) irradiation. Referring to FIG. 6, the film 40 is removed from the mask 20, leaving the light emitting elements 42 secured on the base 10. At last, as shown in FIG. 7, the mask 20 is removed from the base 10 by a process of such as etching etc. In the present disclosure, the position and amount of the glue 30 may be well controlled by using the patterned mask 20, whereby the light emitting elements 42 may be precisely positioned on the base 10. More importantly, the glue 30 is positioned on the base 10 at one time, and the light emitting elements 42 are also secured on the base 10 at one time, making the bonding process easy and effective.

It is noted that, the light emitting elements 42 electrically connecting with the electrical structures of the base 10 may be achieved in various ways. For instance, the glue 30 may be conductive, and in the Step D, the light emitting elements 42 are electrically connected to the electrical structures of the base 10 via the conductive glue 30 by a flip chip technology. The light emitting elements 42 may also be electrically connected to the electrical structures of the base 10 by wire bonding after Step F.

Specifically, after Step F, an encapsulant layer (not shown) may encapsulate the light emitting elements 42. Further, a phosphor layer may also be positioned on the encapsulant layer. The phosphor layer may contain YAG phosphors, silicon oxynitride phosphors, or nitride phosphors, etc. In an alternative embodiment, the phosphor may be scattered in the encapsulant layer.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A method of packaging a light emitting device comprising:
A) providing a base;
B) forming a mask on the base, the mask defining a plurality of holes therein;
C) applying glue in each of the holes;
D) positioning a film on the mask, a plurality of light emitting elements being secured on the film, and each of the light emitting elements being positioned in a corresponding hole and adhered by the glue in the corresponding hole;
E) separating the light emitting elements from the film and removing the film from the mask; and
F) removing the mask from the base.

2. The method of claim 1, wherein the base forms electrical structures thereon, the glue is conductive and electrically connects with the electrical structure, and the light emitting elements are electrically connected to the electrical structures by a flip chip technology in step D.

3. The method of claim 1, wherein the base forms electrical structures thereon, and the light emitting elements are electrically connected to the electrical structures by wire bonding technology after step F.

4. The method of claim 1, wherein the light emitting elements are adhered on the film.

5. The method of claim 4, wherein in step E, the light emitting elements are separated from the film by subjecting the film to ultraviolet irradiation.

6. The method of claim 1 further comprising a step of encapsulating the light emitting elements with an encapsulant layer after step F.

7. The method of claim 6, further comprising a step of positioning a phosphor layer on the encapsulant layer.

8. The method of claim 6, wherein the encapsulant layer contains phosphors scattered therein.

9. The method of claim 1, wherein the light emitting elements are light emitting diodes.
